(19) United States
(12) Patent Application Publication
(10) Pub. No.: US 2015/0058704 A1
(43) Pub. Date: Feb. 26, 2015

(54) PARAMETERIZED INTERLEAVER FOR A MULTI-RATE SYSTEM

(71) Applicant: Sirius XM Radio Inc., New York, NY (US)

(72) Inventors: Ed Schell, Jackson, NJ (US); Carl Scarpa, Plainsboro, NJ (US)

(21) Appl. No.: 14/467,884

(22) Filed: Aug. 25, 2014

Related U.S. Application Data
(60) Provisional application No. 61/869,182, filed on Aug. 23, 2013.

(51) Int. Cl. H03M 13/27

(52) U.S. Cl. CPC H03M 13/2732; H03M 13/2792
USPC 714/786

(57) ABSTRACT

A parameterized interleaver structure is presented. The interleaver is designed to specify and maintain a maximum delay, irrespective of code rate and number of code blocks. The disclosed interleaver in effect concatenates two interleaver structures together. When the arm index is greater than a defined number N1, the arm delay is calculated using a set of parameters M2, D2, and N, where M2 is a maximum delay for an interleaver arm, D2 is the delay decrement, and N is the arm index, running from 1 to N, where N is the total number of arms in the interleaver. However, when the arm index N is less than or equal to N1, the delay can be calculated in a similar manner, but using a second set of parameters, namely M1, D1, and N instead, which involves a different delay length. This approach has the dual benefit of specifying both the maximum delay of the interleaver and the minimum required delay to process data.

### CROSS-REFERENCE TO RELATED APPLICATIONS

This application claims the benefit of U.S. Provisional Patent Application No. 61/869,182, filed on Aug. 23, 2014, entitled “PARAMETERIZED INTERLEAVER FOR A MULTI-RATE SYSTEM,” the disclosure of which is hereby incorporated herein by this reference as if fully set forth.

### TECHNICAL FIELD

The present invention relates generally to digital coding and framing of signals on a communications path, and in particular to a parameterized interleaver for a multi-rate system.

### SUMMARY OF THE INVENTION

A parameterized interleaver structure is presented. The interleaver is designed to specify and maintain a maximum delay, irrespective of code rate and number of code blocks. The disclosed interleaver in effect concatenates two interleaver structures together. When the arm index is greater than a defined number N1, the arm delay is calculated using a set of parameters M2, D2, and N, where M2 is a maximum delay for an interleaver arm, D2 is the delay decrement, and N is the arm index, running from 1 to N, where N is the total number of arms in the interleaver. However, when the arm index N is less than or equal to N1, the delay can be calculated in a similar manner, but using a second set of parameters, namely M1, D1, and N instead, which involves a different delay length. This approach has the dual benefit of specifying both the maximum delay of the interleaver and the minimum required delay to process data.

### BRIEF DESCRIPTION OF THE DRAWINGS

FIG. 1 illustrates an exemplary standard convolutional interleaver;

FIG. 2 illustrates an exemplary uniform convolutional interleaver;

FIGS. 3-5 illustrate arm lengths of exemplary interleavers for respective delays of 0.25, 1.0, and 0.2, respectively, all other interleaver parameters being equal;

FIG. 6 depicts an exemplary multi-rate interleaver according to an exemplary embodiment of the present invention; and

FIG. 7 depicts an alternate multi-rate interleaver according to an exemplary embodiment of the present invention.

### DETAILED DESCRIPTION OF THE INVENTION

Modern communication systems are often designed to be completely flexible. Thus, they generally contain the flexibility to simultaneously have different modulation, throughputs, delays, and coding rates merged within the same transmission scheme. These options are often programmable, and can be altered with a simple configuration change. One of the challenges comes in designing a convenient and sensible interleaver structure that can easily accommodate the inherent flexibility in these modern designs. Exemplary embodiments of the present invention include a new parameterized interleaver structure that is capable of addressing this problem.

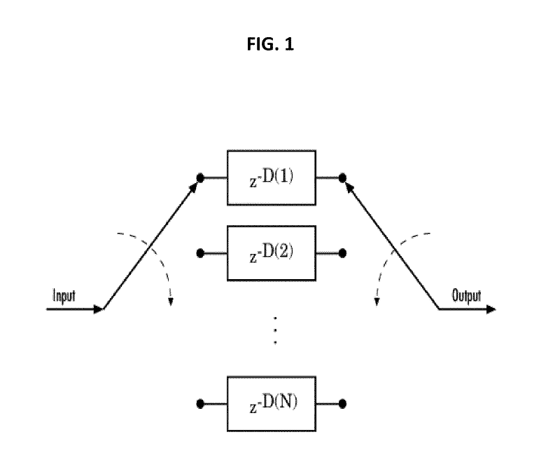

Communication systems commonly employ a convolutional interleaver, as shown in FIG. 1. The depicted interleaver delivers a fixed number of input bits on each arm, rotating through all the arms before repeating the sequence. Each arm contains a FIFO of some configurable delay size. In the general case, the delay size of each arm can be any arbitrary size, depending on the desired dispersion effect. Synchronized to the input, the interleaver delivers an equal number of bits from the output of the FIFO on each interleaver arm.

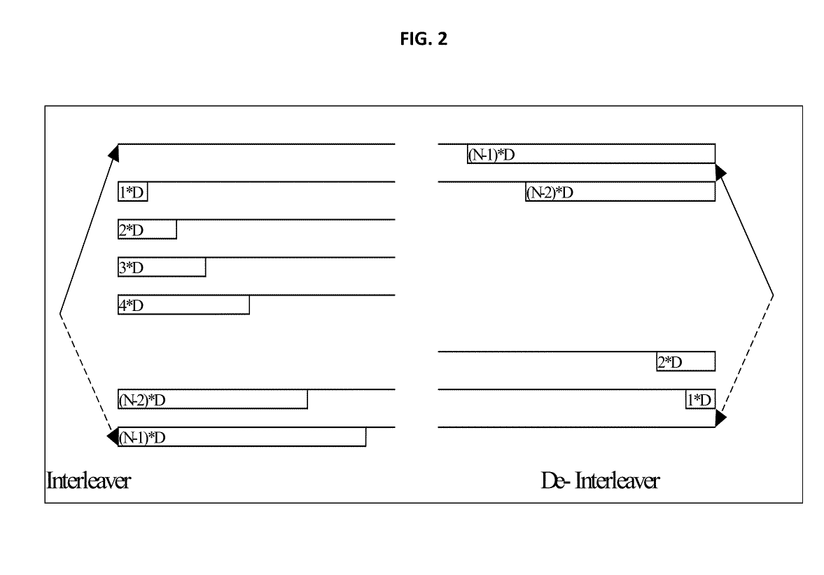

FIG. 2 illustrates a more specific case of an interleaver, namely a uniform convolutional interleaver, where the delay size of each arm begins at zero and increments a fixed amount for each subsequent arm. Such an interleaver is described by the number of arms (N), the delay unit increment per arm (D), and the size (S) of the delay unit (usually in bits or bytes). FIG. 2 illustrates an example of a uniform convolutional interleaver.

The goal of the interleaver is to spread the encoded data in time, such that any momentary channel distortions, such as, for example, Fades, are evenly distributed to all of the encoded data blocks. If a fade is properly distributed, each coded block of data will experience a portion of the fade, allowing Forward Error Correction (“FEC”) processing to recover the faded data without errors. If there were no interleaver, or if there was an insufficient interleaver, the FEC would fail to decode the data, resulting in errors in the final output. The effectiveness of the interleaver is thus dependent upon (i) the maximum delay and (ii) the distribution of delays amongst its various arms.

In order for every coded block of data to experience the same delay profile, the number of arms of the interleaver must divide evenly into the code block. Unfortunately, finding a common result that works for all code rates is extremely difficult when considering a system with a large selection of possible code rates, where each code rate results in a unique block size. Therefore, in exemplary embodiments of the present invention, an interleaver structure allows for each code rate to have a different number of arms. Regardless of the code rate used in a block, each code block will be delivered in a single pass through the arms, beginning at the first arm for each new code block and stopping at every other arm in the interleaver exactly once. The number of arms is fixed within a system for each code rate, specified by the parameter N. The size of N depends on the size of the delay unit, denoted by the parameter S. This also determines the number of symbols at a given time that are delivered to the interleaver arm. In exemplary embodiments of the present invention, the value of S may, for example, be chosen as common factor to all the code rates, in order to get the best memory efficiency in an actual implementation. However, in order to reach a common number for all of the different rates, it may be necessary in some embodiments to pad the block size. Table 1 below provides an exemplary set of interleaver parameters for a particular family of code rates with an uncoded data size of 12168 bits.

TABLE 1

| Code Rate | 1/3 | 3/8 | 2/5 | 3/7 | 1/2 | 6/11 | 3/5 | 2/3 | 3/4 | 6/7 |
|---|---|---|---|---|---|---|---|---|---|---|
| Pad Blk Size | 36576 | 32544 | 30432 | 28416 | 24384 | 22368 | 20352 | 18336 | 16320 | 14208 |
| IU Size (S) | 96 | 96 | 96 | 96 | 96 | 96 | 96 | 96 | 96 | 96 |
| Number of | 381 | 339 | 317 | 296 | 254 | 233 | 212 | 191 | 170 | 148 |
| Arms (N) | | | | | | | | | | |

When a common interleaver structure is shared amongst different symbol modulations, code rates, and numbers of code blocks, determining the maximum delay of the interleaver in units of time can be difficult. Thus, in exemplary embodiments of the present invention, the maximum delay may be specified as multiples of a Master Frame unit. It noted that in a system where multiple streams of data are multiplexed together, they are often synchronized to a larger unit of time called the Master Frame. For example, it may be assumed that the Master Frame duration is 0.5 seconds. Therefore, in exemplary embodiments of the present invention, an exemplary interleaver structure can first be specified by setting the maximum desired delay experienced by a given datastream to be integer multiples of the Master Frame, here 0.5 s. This parameter will be denoted M2 in this disclosure.

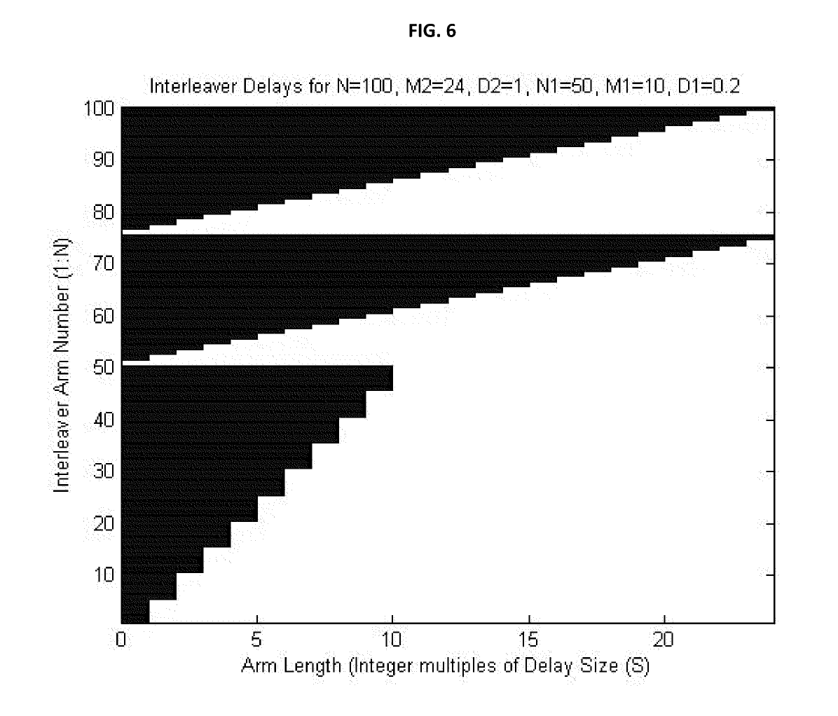

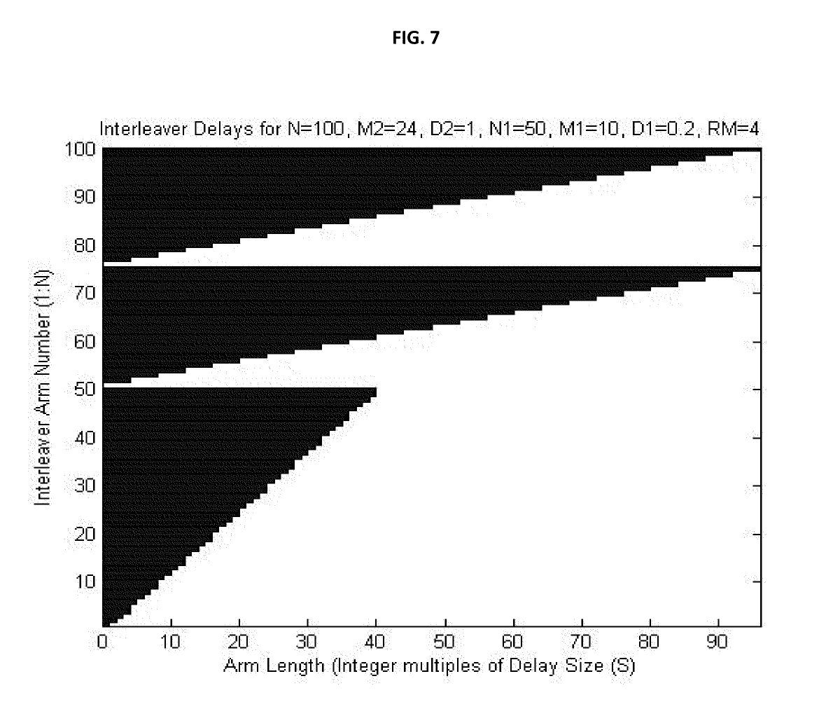

Because the interleaver structure begins with setting the maximum delay, an accompanying parameter must also be included to provide a size decrement for the remaining arms. This parameter will be denoted by D, D1 or D2 herein (D refers to a delay unit generally. D2 refers to the longer delay unit in a multi rate interleaver, as shown in FIGS. 6-7, and D1 to the shorter delay unit in such a structure; in some contexts, if there is no D1, the maximum delay operative for the entire interleaver can be referred to as D2). The value of, for example, D2 may be presented as either a fraction or an integer number. The delay of the branches can thus be calculated as follows:

D(i)=M2−MOD(Floor((N−i)*D2)), (M2+1), where i=the current arm index from 1 to N Equation A

Where, Floor(x) is the largest integer not greater than x, and Mod(A), (B) is the modulus or remainder after dividing A by B. Thus, for example, Floor (2.4)=2, and Mod(26), (5)=1.

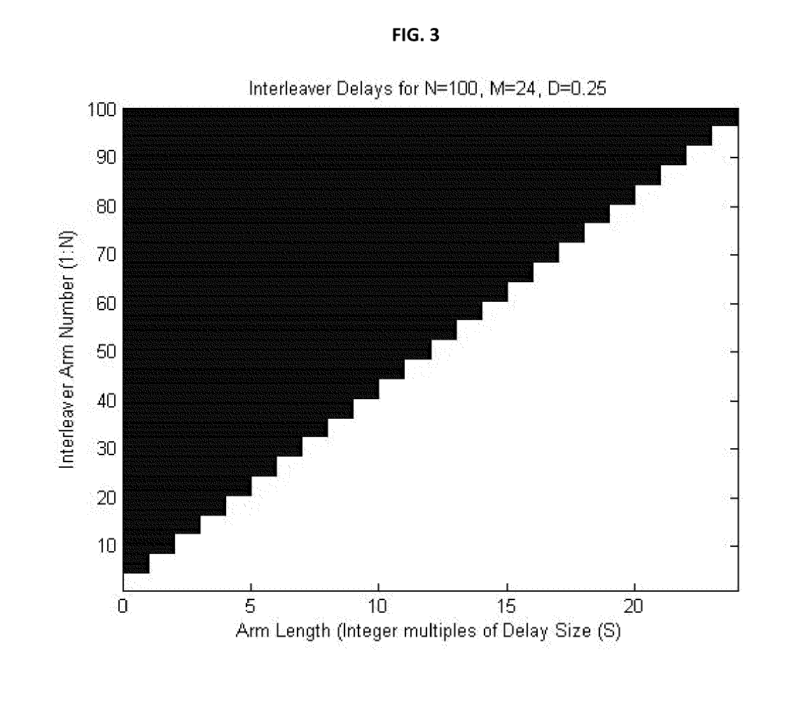

It is noted that for values of D2 less than one, the delay may not change over a given number of nearby interleaver branches. This situation is depicted in FIG. 3, where the delay unit D2 is 0.25, and thus there are only 25 separate delay lengths used for the 100 arms of the exemplary interleaver. Thus, for example, for arms N=1:4, the delay is 0, for arms N=5:8, the delay is 1, for arms N:9-12, the delay is 2, and continuing in this fashion until the delay for the last four arms, N=96:100, is 24, the maximum delay D2 of this interleaver.

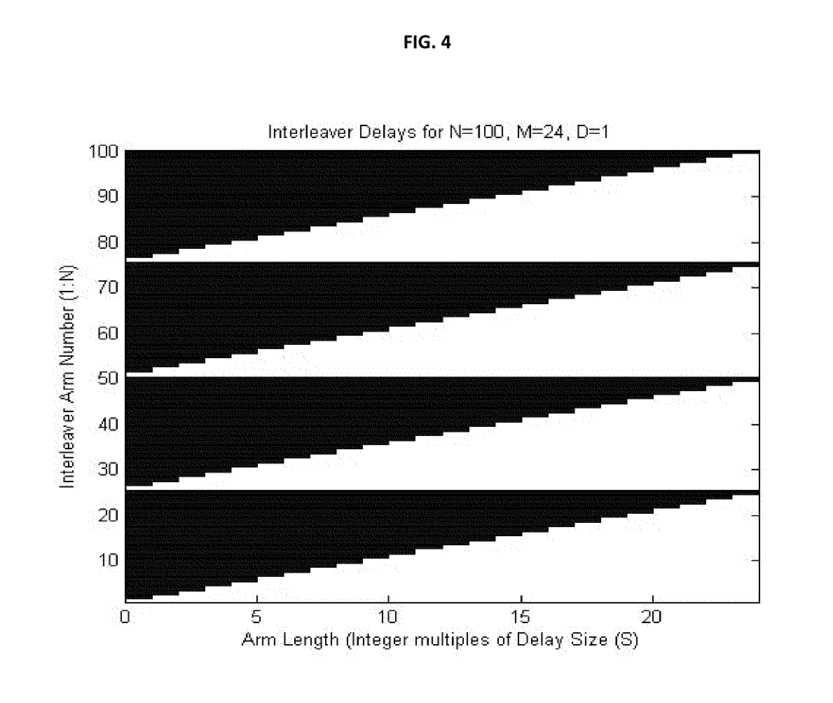

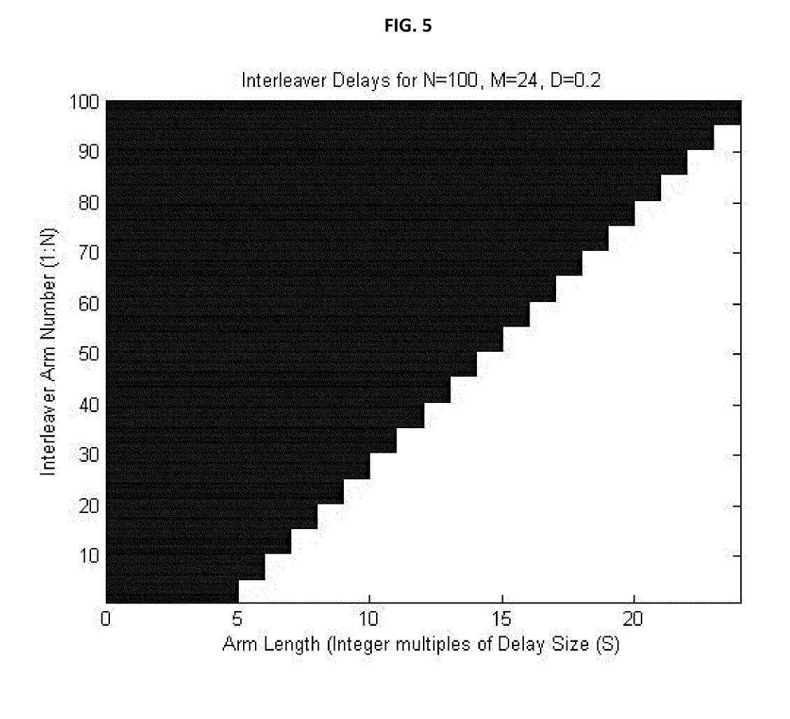

On the other hand, if the decrement D2 is large enough, the delay pattern may repeat across various sets of the arms, as is depicted in FIG. 4, where due to a delay D2=1, the delay values for arms having N:1-25 are respectively the same as those arms having N:26-50, N:51-75 and N:76-100, where all four of these ranges of N run through the delay values 0-24, 24 being the maximum delay in this example as well. Alternatively, if the delay decrement is very small, decrementing down from the largest arm, say N=100, it may never reach zero, resulting in a bulk delay of all the data, as shown in FIG. 5. Here, the delay at arm N=100 starts out at D2=24, the maximum delay. But because the decrement for each arm for N less than 100 is so small, and given the delay as calculated by Equation A, provided above, the Floor( ) operator rounds down to the lowest contained integer so that successive arms have the same delay, because for small enough delay decrement D2, the factor Floor((N−i)*D2) stays at the same value even though I decreases. For example, for arms 6, 7 and 8 the delay calculation is as follows:

D(8)=24−MOD(Floor(92*0.2)), (24+1)=24−MOD(18), (25)=24−18=6;

D(7)=24−MOD(Floor(93*0.2)), (24+1)=24−MOD(18), (25)=24−18=6;

D(6)=24−MOD(Floor(94*0.2)), (24+1)=24−MOD(18), (25)=24−18=6,

and they all have a delay of 6.

Similarly, for arms 76, 77 and 78, the delay calculation is as follows:

D(78)=24−MOD(Floor(22*0.2)), (24+1)=24−MOD(4), (25)=24−4=20;

D(77)=24−MOD(Floor(23*0.2)), (24+1)=24−MOD(4), (25)=24−4=20;

D(76)=24−MOD(Floor(24*0.2)), (24+1)=24−MOD(4), (25)=24−4=20,

and they all have delay equal to 20.

Moreover, because D2 is so small, the factor (N−i)*D2 never reaches zero. This results in every interleaver arm in the example, of FIG. 5 having at least the minimum delay of 5, which is in effect a “bulk delay” of 5, and the actual range of delays thus being between 5-24.

It is noted that the examples depicted in FIGS. 3-5 show the arm delays from the receiver perspective (the delays being shown in the blue (dark) bars at the left side of each plot). Thus, a transmitter would implement the complement of this structure (essentially the white background), and thus given the interleaving on the transmitter and the de-interleaving process on the receiver the overall delay is uniform for data in any arm. As can readily be noted, in each of FIGS. 3-5, the parameters N (number of arms) and M (maximum delay) are constant, the only variance being in D, the unit delay length. Thus, FIG. 3 illustrates arm length for a delay of 0.25, FIG. 4 arm length for a delay of 1.0, and FIG. 5 illustrates arm length for a delay of 0.2. The three effects illustrated and described above are thus all the effect of only varying the delay length D.

It is noted that the minimum system latency introduced by an interleaver is dependent on the FEC. For a given code rate R, advanced coding systems, such as, for example, Turbo or LDPC, can potentially decode the data with a little more than R*100% of the encoded symbols present, given a high enough SNR. For example, a rate ½ code can begin decoding the data with little more than ½ the number of interleaver arms filled with good data, i.e., it only needs about 50% of the encoded symbols to start decoding accurtaely. Therefore, the minimum delay of a rate ½ code depends on the size of the longest arm that is needed to supply a little more than ½ of the data to the FEC after startup. In the case of the uniform interleaver of FIG. 2, for example, this delay would be N/2*D. Knowing the code rate, in exemplary embodiments of the present invention, the interleaver structure can take advantage of this fact by providing additional parameters so as to set a lower maximum delay within a subsection of the interleaver arms. These additional parameters are denoted M1, D1, and N1, representing the Maximum Delay, Delay Decrement, and Highest Arm Number, respectively, for the substructure.

Essentially, the inventive interleaver concatenates two interleaver structures together. When the arm index is greater than N1, the arm delay is calculated using the M2, D2, and N parameters, as before. However, when the arm index is less than or equal to N1, the delay can be calculated in a similar manner, but using the additional M1, D1, and N1 parameters instead, which involves a different delay length. This novel approach has the dual benefit of specifying both the maximum delay of the interleaver and the minimum required delay to process data. FIG. 6 illustrates an exemplary configuration combining the two distinct parameter sets. With reference thereto, there is a maximum delay of 24 frames and a shorter delay of 10 frames within ½ of the number of arms. Thus, N1 is here set to 50. Alternatively, for a code rate of ⅓, for example, N1 could be set to 33 or 34.

An additional component of the disclosed design is the ability to specify a rate multiple. As described thus far, the interleaver parameters were defined with reference to what a single code block would experience. However a more likely scenario is that multiple code blocks are sent for a given rate within the same Master Frame unit. While it is possible to envision multiple parallel interleaver structures working independently on each code block, a more convenient approach is to aggregate these into a single structure for a given rate. In order to do so, an additional parameter representing the number of code blocks within a Master Frame Unit for a given rate can be used, denoted as RM or “Rate Multiple.” In this manner, every code block will still experience the same delay profile within a single structure. The application of this number is a simple scaling of the M1, M2, D1, and D2 parameters by RM. This is shown in FIG. 7, for example, where the RM factor is equal to 4.

The following is sample Matlab code that can be used to build the exemplary interleaver structure depicted in FIG. 7, which implements a Rate Multiple of 4, as noted. It may also be used to build the exemplary interleaver structure of FIG. 6, if RM is set to 1 instead of 4 (i.e., no Rate Multiple used).

| %%%%%%%%%%%%%% | |
|---|---|
| % Interleaver Parameter set | |
| RM = 4; | %Rate Multiple |
| N =100; | %Number of Arms |
| M1 = 10; | %Max Depth of 1st stage |
| M2 = 24; | %Max Depth of 2nd stage |
| N1 = 50; | %Arm number for cutoff of 1st stage |
| D1 = 0.2; | %Rate Decrementer for 1st stage |
| D2 = 1; | %Rate Decrementer for 2nd stage |

% Initial parameters
armLen=zeros(1,N);
M=M2*RM;
D=D2*RM;
% Delay calculation
for i=N:−1:1

if(i==N1)

% Reset length to stage 1 max delay
M = M1*RM;
D=D1*RM;
N=N1;

end
armLen(i) = M − mod(fix((N−i)*D),M+RM);

end
%%%%%%%%%%%%%%

Thus, FIG. 7 illustrates a recreation of the example used in FIG. 6, but utilizing a rate multiple of RM=4. It is noted that in the example of FIG. 7 the interleaver structure is nearly identical to that of FIG. 6, with the exception that in the example shown in FIG. 7 every delay has experienced a 4× increase due to the rate multiple. It is noted, however, that the overall delay is still the same inasmuch as 4 times the amount of data is being pushed through the interleaver during the same amount of time. Further, by inspection of FIGS. 6 and 7, one readily sees the more smooth transitions of delay as a function of arm index in both subsections of the interleaver. This is desirable, and thus by integrating four times the data that is present in the interleaver (and thus diffused) at any given time, such as shown in FIG. 7, a smoother slope, or variation in delay with interleaver arm is seen, as shown in FIG. 7. RM values may be, obviously whatever number is convenient, such as, for example, 6, 8, 12, 16, etc.

The interleaver structure described above provides a unique approach to dealing with multi-rate systems. A convenient parameterized approach allows the specification of Maximum delays, common across all rate definitions. The concatenation of two independent stages takes advantage of the higher performing iterative decodes by providing early access to the data with a Minimum Delay specification. Finally, the concept of a rate multiplier makes it easy to aggregate the interleaving into a single structure, providing the same delay profile for each code block regardless of the amount of data being transmitted for a given rate.

The Rate Multiple is the number of code blocks being transmitted within a Master Frame Unit. The number of code blocks being transmitted is dependent on the code rate chosen for the data, the size of the Master Frame Unit, and how much of that Master Frame Unit the user wants to allocate to that code rate. The extension to this is a Master Frame Unit consisting of multiple “Pipes” of data, each with its own code rate and interleaver structure.

The advantage of the disclosed design is the programmability to come up with an array of possible structures to meet all needs. These values may depend upon the code rate and the type of channel it is being deployed in. For example, the novel interleaver disclosed herein may be used in a satellite radio communications system, such as that provided by Sirius XM Radio Inc., assignee hereof. Such a satellite radio broadcasting service has a combination of terrestrial and satellite based signals that each receiver receives, such as Satellite Mobile, Terrestrial Mobile, etc. For example, the satellite channel can experience long signal blockage, such as when a vehicle having an SDARS receiver goes under a bridge. This would require a large value for M2 (multiple seconds), enough to be longer than such long signal blockages. However, inasmuch as that is not the normal case, one would also want to determine the *minimum* delay time interval, set to allow the receiver to decode data under good conditions. Thus, M1 could here be used to speed up the startup and recovery time by setting N1 equal to the minimum number of segments needed to decode the signal under high SNR.

As regards the Terrestrial channel, it does not experience long blockages, but can still benefit from an interleaver. In this case, however, M2 may be set much lower than the multiple second delay for the Satellite channel, here say 1-2 seconds, and M1/N1 (the parameters for a faster subsection of the interleaver) may not be used at all (i.e., set to zero).

Another consideration is the code rate. For higher code rates, for example, ⅔, trying to specify a fast startup and recovery period with M1 becomes impractical, as the performance would be dominated by this lower maximum delay section. Therefore, in such a high code rate situation, one might choose to set M1 and N1 to zero as with the terrestrial case, and only use M2 to set the maximum delay, resorting back to a standard convolutional interleaver approach.

It is understood that there are many shades of grey in between these example scenarios, and thus the flexibility provided by the novel interleaver structure allows one to adapt it to any foreseeable situation. It is also noted that anytime a given interleaver structure is desired to be modified, all that need be done is to send the revised parameters M2, D2, M1, D1, N and N1 to a receiver, and the interleaver can be revised or tweaked.

Extensions to More than Two Sub-Sections; Variation in Delay Values

The structure of two combined interleavers into one is not limited to two subsections. There can thus be, in alternate exemplary embodiments according to the present invention, a further set of parameters N3, D3 and M3, where N3<N1, and for interleaver arms 1 through N3, the parameters D3 and M3 are used, for arms (N3+1) through N1 parameters D1 and M1 are used, and, as before, for arms N>N1, the parameters D2 and M2 can be used.

Additionally, an effective bulk delay may be added to (or subtracted from) each arm in a subsection, if desired. For example, looking at FIG. 6, it is useful in some contexts to have the smoothly changing delay values as a function of the arm number seen in the upper portion of the plot, in arms where N goes from 51-100. But as can be seen, and as explained in connection with FIG. 4, because the D2 value is 1.0, the values of the delays repeat in two portions of arms 51-100. In some exemplary embodiments it may be useful to run the delays in the M2, D2 portion of the interleaver (i.e., all arms who index>N1) from the M2 value down to the M1 value, but not going below M1, such as to 0, for example. Thus, in FIG. 6, arms 100 to 51 would run from 24 down to 10, or 11, for example, and only the lower portion of the interleaver actually have delays less than 10. This adds a bulk delay to each arm above N1, effectively. This can be handled by adding a delay to some arms in the D(i) equation (Equation A), or for example, by adjusting D2 such that is smoothly varies from M2 to M1, depending upon the desired values. Various permutations are understood to be possible, and all within the scope of the present invention.

As noted, the ratio of M2 to M1 can be larger, or much smaller than, that shown in FIGS. 6 and 7, depending upon the code rates, channel characteristics and other factors applying to any given real world system.

Finally, as noted, it is useful to push in one full frame of data to an interleaver, and push one out, in a given time interval. Thus, the interleaver parameters may be chosen to achieve this. However, if the timing is not fully exact, a bulk delay can be added to (or subtracted from) the interleaver arms, as noted above, so as to synchronize interleaver cycles with frame boundaries in various exemplary embodiments.

Exemplary Systems

In exemplary embodiments of the present invention, any suitable programming language may be used to implement the routines of particular embodiments including C, C++, Java, JavaScript, Python, Ruby, CoffeeScript, assembly language, etc. Different programming techniques may be employed such as procedural or object oriented. The routines may execute on a single processing device or multiple processors. Although the steps, operations, or computations may be presented in a specific order, this order may be changed in different particular embodiments. In some particular embodiments, multiple steps shown as sequential in this specification may be performed at the same time

Particular embodiments may be implemented in a computer-readable storage device or non-transitory computer readable medium for use by or in connection with the instruction execution system, apparatus, system, or device. Particular embodiments may be implemented in the form of control logic in software or hardware or a combination of both. The control logic, when executed by one or more processors, may be operable to perform that which is described in particular embodiments.

Particular embodiments may be implemented by using a programmed general purpose digital computer, by using application specific integrated circuits (“ASICs”), programmable logic devices, field programmable gate arrays, optical, chemical, biological, quantum or nano-engineered, systems, components and mechanisms. Such embodiments may be implemented using both ASICs and general purposes computers or data processors, or standard chipsets, for example, distributing different functions across various possible elements and modules, either hardware or software. In general, the functions of particular embodiments may be achieved by any means as is known in the art. Distributed, networked systems, components, and/or circuits may be used. Communication, or transfer, of data may be wired, wireless, or by any other means.

Particular embodiments may be implemented in both a transmitter and a receiver of a broadcast communications system and service, such as, for example, a satellite radio service, or an SDARS. The transmitter based interleaver may be implemented in software, for example, and the receiver based interleaver in an ASIC. Parameters, including, for example, M2, M1, N, N1, D2 and D1, and, if applicable, N3, D3 and M3m may be passed from the transmitter to the receiver at any time, thus modifying the interleaver on the receiver as may be desired.

It will also be appreciated that one or more of the elements depicted in the drawings/figures may also be implemented in a more separated or integrated manner, or even removed or rendered as inoperable in certain cases, as is useful in accordance with a particular application. It is also within the spirit and scope to implement a program or code that may be stored in a machine-readable medium, such as a storage device, to permit a computer to perform any of the methods described above.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

While there have been described methods for providing a multi-rate interleaver in a variety of operational modes, it is to be understood that many changes may be made therein without departing from the spirit and scope of the invention. Insubstantial changes from the claimed subject matter as viewed by a person with ordinary skill in the art, no known or later devised, are expressly contemplated as being equivalently within the scope of the claims. Therefore, obvious substitutions now or later known to one with ordinary skill in the art are defined to be within the scope of the defined elements. The described embodiments of the invention are presented for the purpose of illustration and not of limitation.

1. A method of interleaving data in a datastream, comprising:
providing an interleaver with N arms, a first maximum delay M2, a second maximum delay M1, a first delay unit D2 and a second delay unit D1;
specifying a number of arms N1 of the interleaver to have parameters M1 and D1, the remaining arms having parameters D2 and M2; and
interleaving data using the provided interleaver,
wherein N1 is less than N, and
wherein arms 1 through N1 have parameters M1 and D1, and arms N1+1 through N have parameters M2 and D2.

2. The method of claim 1, wherein the arm number N1 is a function of the code rate of the datastream being interleaved,

3. The method of claim 2, wherein at least one of:
(i) for a code rate of ½, N1 equals N/2,
(ii) for a code rate 1/k, 1/k being less than 1, N1 equals N/k,
(iii) N1 is N/2, and
(iv) M2 is one of 24 and 30, M1 is one of 12 and 10, D2 is one of 1.0 and 0.5, and D1 is one of 0.2 and 0.25.

4. (canceled)

5. The method of claim 1, wherein at least one of:
(i) M2 is set equal to an integer multiple of a relevant master frame,
(ii) each of M2 and M1, D2 and D1 are multiplied by a rate multiple RM,
(iii) each of M2 and M1, D2 and D1 are multiplied by a rate multiple RM, and said rate multiple RM is at least one of: (i) set to a number of code blocks transmitted within a defined time, and (ii) equal to one of 4, 6, 8, 12, and 16, and
(iv) M2 is one of 24 and 30, M1 is one of 12 and 10, D2 is one of 1.0 and 0.5, and D1 is one of 0.2 and 0.25.

6-8. (canceled)

9. The method of claim 1, wherein at least one of:
each of M2 and M1, D2 and D1 are multiplied by a rate multiple RM, and wherein said rate multiple RM is set to a number of code blocks transmitted within a master frame unit, and
each of N, N1, M2 and M1, D2 and D1 are at least one of pre-set in a receiver, sent over a communications path to a receiver, and updateable.

10. (canceled)

11. The method of claim 1, wherein the delay for any arm N is calculated as follows:
D(i)=M2−MOD(Floor((N−i)*D2)), (M2+1),
where i=a current arm index from 1 to N, Floor(x) is the largest integer not greater than x, and Mod(A), (B) is the modulus or remainder after dividing A by B.

12. A non-transitory computer readable medium containing instructions that, when executed by at least one processor of a computing device, cause the computing device to:
provide an interleaver with N arms, a first maximum delay M2, a second maximum delay M1, a first delay unit D2 and a second delay unit D1;
specify a number of arms N1 of the interleaver to have parameters M1 and D1, the remaining arms to have parameters D2 and M2; and
interleave data using the provided interleaver,
wherein N1 is less than N, and
wherein arms 1 through N1 have parameters M1 and D1, and arms N1+1 through N have parameters M2 and D2.

13. The non-transitory computer readable medium of claim 12, wherein the arm number N1 is a function of the code rate of the datastream being interleaved.

14. The non-transitory computer readable medium of claim 12,
wherein at least one of:
(i) for a code rate of ½, N1 equals N/2,
(ii) for a code rate 1/k, 1/k being less than 1, N1 equals N/k, and
(iii) N1 is N/2.

15. (canceled)

16. The non-transitory computer readable medium of claim 12, wherein N1 is one of N/2 and N/3.

17. The non-transitory computer readable medium of claim 12, wherein at least one of:
(i) M2 is set equal to an integer multiple of a relevant master frame;
(ii) each of M2 and M1, D2 and D1 are multiplied by a rate multiple RM,
(iii) each of M2 and M1, D2 and D1 are multiplied by a rate multiple RM, which is at least one of: set to a number of code blocks transmitted within a defined time, and equal to one of 4, 6, 8, 12, and 16, and
(iv) M2 is one of 24 and 30, M1 is one of 12 and 10, D2 is one of 1.0 and 0.5, and D1 is one of 0.2 and 0.25.

18-19. (canceled)

20. The non-transitory computer readable medium of claim 12, wherein at least one of:
each of M2 and M1, D2 and D1 are multiplied by a rate multiple RM, and wherein said rate multiple RM is set to a number of code blocks transmitted within a master frame unit, and
each of N, N1, M2 and M1, D2 and D1 are at least one of pre-set in a receiver, sent over a communications path to a receiver, and updateable.

21. (canceled)

22. The non-transitory computer readable medium of claim 12, wherein the delay for any arm N is calculated as follows:
D(i)=M2−MOD(Floor((N−i)*D2)), (M2+1),
where i=a current arm index from 1 to N, Floor(x) is the largest integer not greater than x, and Mod(A), (B) is the modulus or remainder after dividing A by B.

23. A system, comprising:
at least one processor; and
memory containing instructions that, when executed, cause the at least one processor to:
provide an interleaver with N arms, a first maximum delay M2, a second maximum delay M1, a first delay unit D2 and a second delay unit D1;
specify a number of arms N1 of the interleaver to have parameters M1 and D1, the remaining arms to have parameters D2 and M2; and
interleave data using the provided interleaver,
wherein N1 is less than N, and
wherein arms 1 through N1 have parameters M1 and D1, and arms N1+1 through N have parameters M2 and D2.

24. The system of claim 23, wherein the arm number N1 is a function of the code rate of the datastream being interleaved.

25. The system of claim 24, wherein at least one of:
(i) for a code rate 1/k, 1/k being less than 1, N1 equals N/k,
(ii) N1 is one of N/2 and N/3,
(iii) M2 is set equal to an integer multiple of a relevant master frame,
(iv) each of M2 and M1, D2 and D1 are multiplied by a rate multiple RM, and
(iv) each of M2 and M1, D2 and D1 are multiplied by a rate multiple RM, which is at least one of
set to a number of code blocks transmitted within a defined time,
and equal to one of 4, 6, 8, 12, and 16.

26-29. (canceled)

30. The system of claim 23, wherein each of N, N1, M2 and M1, D2 and D1 are one of pre-set in a receiver, sent over a communications path to a receiver, and updateable.

31. The system of claim 23, wherein M2 is one of 24 and 30, M1 is one of 12 and 10, D2 is one of 1.0 and 0.5, and D1 is one of 0.2 and 0.25.

32. The system of claim 23, wherein the delay for any arm N is calculated as follows:
D(i)=M2−MOD(Floor((N−i)*D2)), (M2+1),
where i=a current arm index from 1 to N, Floor(x) is the largest integer not greater than x, and Mod(A), (B) is the modulus or remainder after dividing A by B.

33-34. (canceled)
